(19) United States
(12) Patent Application Publication
(10) Pub. No.: US 2005/0074976 A1
(43) Pub. Date: Apr. 7, 2005

(54) Method for polishing copper layer and method for forming copper layer wiring using the same

(76) Inventor: Hyung Jun Kim, Chungcheongbuk-do (KR)

Correspondence Address: LADAS & PARRY LLP, 224 SOUTH MICHIGAN AVENUE, SUITE 1200, CHICAGO, IL, 60604, US

(21) Appl. No.: 10/733,650

(22) Filed: Dec. 11, 2003

(30) Foreign Application Priority Data
Oct. 7, 2003 (KR) 2003-69539

(51) Int. Cl. H01L 21/302

(52) U.S. Cl. 438/692

(57) ABSTRACT

Disclosure is a method for polishing a copper layer and a method for forming a copper layer wiring using the same. The method for polishing the copper layer is carried out through a CMP process by using slurry having a polishing rate of at least 10,000 Å/min. The method for forming the copper layer wiring includes a step of forming a sacrificial layer pattern having a trench on a substrate. Then, the copper layer is continuously formed on a sidewall of the trench, a bottom surface of the trench, and on the sacrificial layer pattern. Then, the copper layer is polished so as to expose a surface of the sacrificial layer pattern by using the method. The copper layer is effectively polished when the method is applied to a polishing process of the copper layer.

### BACKGROUND OF THE INVENTION

1. Field of the Invention

The present invention relates to a method for polishing a copper layer and a method for forming a copper layer wiring using the same, and more particularly to a method for polishing a copper layer through a CMP (Chemical Mechanical Polishing) process by using slurry and a method for forming a copper layer wiring using the same.

2. Description of the Prior Art

In general, as information media such as computers and the like have been widely spread, a semiconductor device also makes great strides. In a functional aspect, it is required that the semiconductor device has a large storage capacity and operates at a high speed. To this end, a semiconductor technology has been developed to improve an integration scale, reliability, and a response speed and the like of the semiconductor device. That is, an MEMS (micro electromechanical system) has been developed.

In order to match with a requirement for such a large scale integration, copper having a lower specific resistance and a better electromigration resistance than aluminum is used for fabricating the semiconductor device. That is, copper is used for fabricating a metal wiring or an inductor and the like.

Since it is difficult to form copper interconnect by conventional dry-etching process, copper is processed through a CMP (Chemical-Mechanical Polishing) process.

Examples of methods for forming a copper layer wiring by means of the CMP process are disclosed in U.S. Pat. Nos. 6,423,637 (issued to Han), and 6,475,914 (issued to Kim). In particular, an example of a method for fabricating an inductor using copper by means of an MEMS is disclosed in U.S. Pat. No. 6,083,802 (issued to Wen, et al).

According to U.S. Pat. No. 6,083,802, a photoresist pattern is used as a sacrificial layer. in order to fabricate a copper inductor. That is, the copper inductor is molded by using the photoresist pattern. At this time, the copper layer is repeatedly polished several times in order to form the copper inductor.

The photoresist pattern is used as a polishing stop layer during copper CMP. However, the photoresist pattern is significantly damaged by CMP process because the photoresist is mechanically weak. For this reason, polishing pressure and a polishing rate are adjusted to a low level in order to reduce an influence on the photoresist pattern. However, when polishing pressure and the polishing rate are adjusted to the low level, increased polishing time is required. Such increased polishing time may have an influence on the photoresist pattern.

Therefore, it frequently happens that such copper layer patterning on photoresist cannot be successfully done by conventional CMP process, because the CMP process for the copper layer cannot be easily performed. Accordingly, there is a problem in that it is difficult to fabricate a large scale semiconductor device by using an MEMS.

### SUMMARY OF THE INVENTION

Accordingly, the present invention has been made to solve the above-mentioned problems occurring in the prior art, and a first object of the present invention is to provide a method capable of polishing a copper layer at a high polishing rate through a CMP process.

A second object of the present invention is to provide a method for forming a copper layer wiring by polishing a copper layer at a high polishing rate through a CMP process.

A third object of the present invention is to provide a method for forming a copper layer wiring such as an inductor by polishing a copper layer at a high polishing rate through a CMP process.

In order to accomplish the first object, according to an aspect of the present invention, there is provided a method for polishing a copper layer, the method comprising the steps of: forming the copper layer on a substrate; and polishing the copper layer through a CMP process, in which slurry having a polishing rate of at least 10,000 Å/min with respect to the copper layer is used.

In order to accomplish the second object, according to another aspect of the present invention, there is provided a method for forming a copper layer wiring, the method comprising the steps of: forming a sacrificial layer pattern having a trench on a substrate; continuously forming a copper layer on a sidewall of the trench, a bottom surface of the trench, and the sacrificial layer pattern; and polishing the copper layer through a CMP process by using slurry having a polishing rate of at least 10,000 Å/min with respect to the copper layer, thereby exposing a surface of the sacrificial layer pattern.

In order to accomplish the third object, according to still another aspect of the present invention, there is provided a method for forming a copper layer wiring, the method comprising the steps of: forming a first sacrificial layer pattern having a first trench on a substrate; continuously forming a first copper seed layer on a sidewall of the first trench, a bottom surface of the first trench, and the first sacrificial layer pattern; polishing the first copper seed layer through a CMP process by using slurry having a polishing rate of at least 10,000 Å/min with respect to the first copper seed layer, thereby exposing a surface of the first sacrificial layer pattern; removing the first sacrificial layer pattern to a height of the first copper seed layer formed on the bottom surface of the first trench, thereby forming a trench structure having the first trench filled with the first copper seed layer; forming a second sacrificial layer pattern having a second trench, which exposes the trench structure, on the first sacrificial layer pattern having the trench structure; continuously forming a second copper seed layer on a sidewall of the second trench, a bottom surface of the second trench, and the second sacrificial layer pattern; continuously forming a copper layer on the second copper seed layer; and sequentially removing the copper layer and the second copper seed layer, thereby exposing a surface of the second sacrificial layer pattern.

In the CMP process for the copper layer or the copper seed layer, a sacrificial layer pattern exposed through the CMP process may be damaged when the polishing rate of the copper layer or the copper seed layer is less than 10,0000 Å/min. Accordingly, in the CMP process of the present invention, slurry having the polishing rate of at least 10,000 Å/min with respect to the copper layer or the copper seed layer is used. More preferably, slurry having the polishing rate of at least 18,000 Å/min with respect to the copper layer or the copper seed layer is used.

Particularly, since slurry having the polishing rate of at least 10,000 Å/min is used, it is possible to employ lower polishing pressure. It is preferred that polishing pressure is set in a range of about 0.1 to 2.0 psi. The reason is that if polishing pressure is less than 0.1 psi, much polishing time is required due to excessively-low polishing pressure, and if polishing pressure is greater than 2.0 psi, the sacrificial layer pattern exposed through the CMP process is damaged.

Polishing pressure and the polishing rate can be applied to the polishing process for the copper layer or the copper seed layer, because slurry including polycarboxylate polymer is used in the polishing process. It is preferred that slurry includes polycarboxylate polymer or composition of polycarboxylate polymer and the like.

An example of composition of polycarboxylate polymer is disclosed in PCT Application NO. PCT/US1997/17943.

As examples for the copper layer wiring, there are wirings for electric connection or passive devices such as copper inductors and the like. Also, as examples for the sacrificial layer pattern, there are insulation layer patterns or photoresist patterns and the like. However, problems occur when the insulation layer patterns are used for fabricating the copper inductors. That is, when the insulation layer patterns are completely removed for fabricating the copper inductors, the copper inductors may be damaged. For this reason, it is preferred to use a photoresist pattern capable of decreasing damage to the copper inductor as a sacrificial layer pattern, instead of a dielectric pattern.

Furthermore, it is possible to form the copper layer or the copper seed layer by means of an electroplating process, physical vapor deposition, or chemical vapor deposition and the like.

As described above, according to the present invention, it is possible to decrease an influence on the sacrificial layer pattern formed below the copper layer when the CMP process for the copper layer is carried out. Accordingly, it is possible to form the copper layer wiring having a required pattern.

### BRIEF DESCRIPTION OF THE DRAWINGS

The above and other objects, features and advantages of the present invention will be more apparent from the following detailed description taken in conjunction with the accompanying drawings, in which:

FIGS. 1A and 1B are sectional views showing a method for polishing a copper layer according to a first embodiment of the present invention;

FIGS. 2A to 2C are sectional views showing a method for forming a copper layer wiring according to a second embodiment of the present invention;

FIGS. 3A to 3F are sectional views showing a method for forming a copper inductor according to a third embodiment of the present invention; and

FIGS. 4A to 4E are perspective views showing a method for forming a copper inductor according to a fourth embodiment of the present invention.

### DETAILED DESCRIPTION OF THE PREFERRED EMBODIMENTS

Hereinafter, a method for polishing a copper layer and a method for forming a copper layer wiring using the same according to the present invention will be described with reference to the accompanying drawings. In the following description and drawings, the same reference numerals are used to designate the same or similar components, and so repetition of the description on the same or similar components will be omitted.

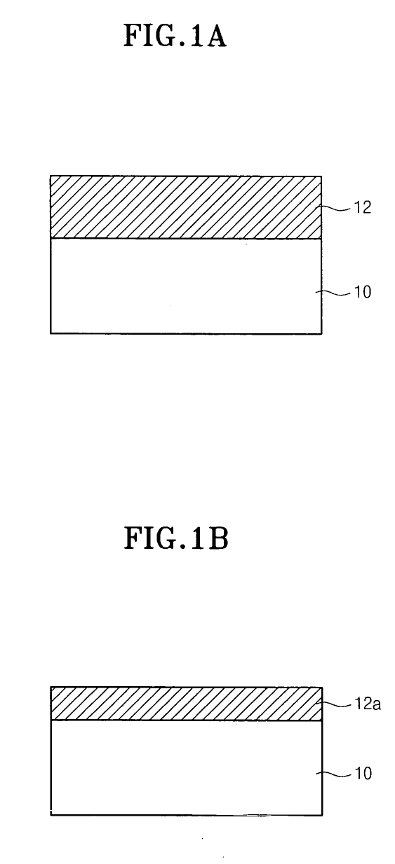

FIGS. 1A and 1B are sectional views showing a method for polishing a copper layer according to a first embodiment of the present invention.

Referring to FIG. 1A, a copper layer 12 is formed on a substrate 10. At this time, the copper layer 12 is formed by means of an electroplating process or a deposition process (chemical vapor deposition or physical vapor deposition) in such a manner that the copper layer 12 has a thickness of about 20 μm .

Referring to FIG. 1B, a CMP process is carried out with respect to the copper layer. At this time, while performing the CMP process, slurry including polycarboxylate polymer is used. Also, polishing pressure is adjusted to about 1 psi. In particular, a polishing rate of the copper layer is adjusted to about 18,000 μ/min by using slurry.

Since it is possible to obtain such a polishing rate and polishing pressure of the copper layer in the CMP process, the copper layer can be efficiently polished. Therefore, recently, the method for polishing the copper layer is actively applied to an MEMS (micro electromechanical system) requiring the high integration degree.

Hereinafter, a method for forming a copper layer wiring according to the present invention will be described in detail with reference to the accompanying drawings.

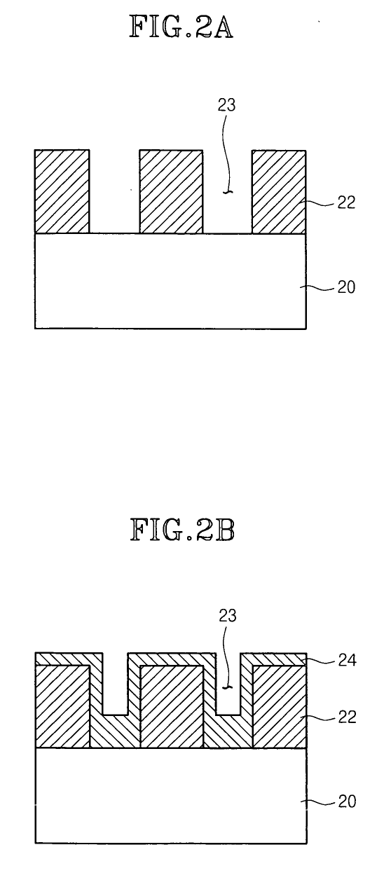

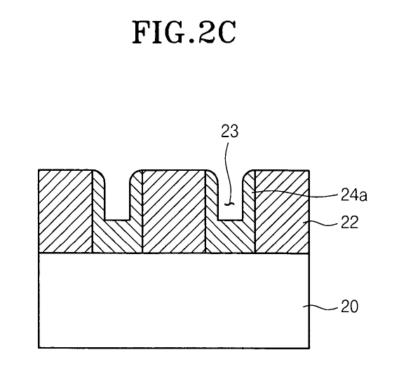

FIGS. 2A to 2C are sectional views showing a method for forming a copper layer wiring according to the second embodiment of the present invention.

Referring to FIG. 2A, a photoresist pattern is formed on a substrate 20 as a sacrificial layer pattern 22 having a trench 23. In detail, a photoresist film is formed on the substrate 20. Thereafter, a portion of the photoresist film, in which the trench 23 is formed, is defined by performing an exposure process. Subsequently, the photoresist film of the portion defined as the trench 23 is removed by performing a development process. As a result, the photoresist pattern 22 having the trench 23 is formed on the substrate 20.

Referring to FIG. 2B, a copper seed layer 24 is continuously formed on a sidewall of the trench 23, a bottom surface of the trench 23, and the photoresist pattern 22. At this time, the copper seed layer 24 is formed by using the electroplating process or the deposition process (chemical vapor deposition or physical vapor deposition). Although it is not shown, after a barrier metal layer, such as a Ti layer, a TiN layer, or a multi layer including a stacked Ti—TiN layer, is continuously formed on the sidewall of the trench, the bottom surface of the trench, and the photoresist pattern, it is possible to form the copper layer on the barrier metal layer.

Referring to FIG. 2C, the copper seed layer 24 is polished in such a manner that a surface of the photoresist pattern 22 is exposed. As a result, the copper seed layer 24 is formed as the copper layer wiring 24a. That is, the copper layer wiring 24a is formed on the sidewall of the trench 23 and the bottom surface of the trench 23. The polishing process for the copper seed layer 24 shown in FIG. 2C is the same as the polishing process for the copper layer explained with reference to FIG. 1B.

Although it is not shown, after polishing the copper seed layer 24, it is preferred to fill the trench 23 with the copper layer and the like using a thin film deposition process such as the electroplating process.

When copper layer is processed through the CMP process in order to form the copper layer wiring, it is possible to achieve such a polishing rate and polishing pressure, so that the copper layer wiring having a required pattern can be formed. Therefore, recently, the method for forming the copper layer wiring can be actively applied to the MEMS requiring the high integration degree.

Although it is not shown, the height of the copper layer wiring can be variously adjusted. That is, after exposing the surface of the photoresist pattern through the CMP process for the copper layer, the photoresist pattern is polished together with the cooper layer wiring of the sidewall formed in the trench in-situ, so that the height of the copper layer wiring can be adjusted. Also, when the photoresist pattern is etched by using a solvent, the copper layer wiring of the sidewall formed in the trench is etched due to an etching selectivity, so that the copper layer wiring can be formed only on the bottom surface of the trench.

Hereinafter, a method for forming a copper layer, particularly a copper inductor according to the present invention will be described in detail with reference to the accompanying drawings.

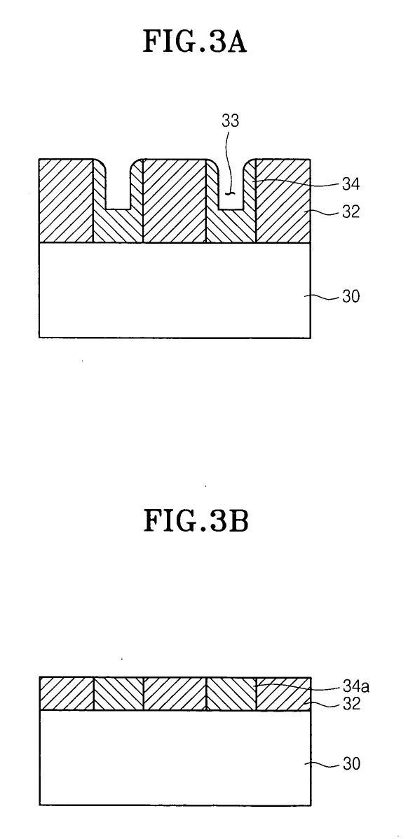

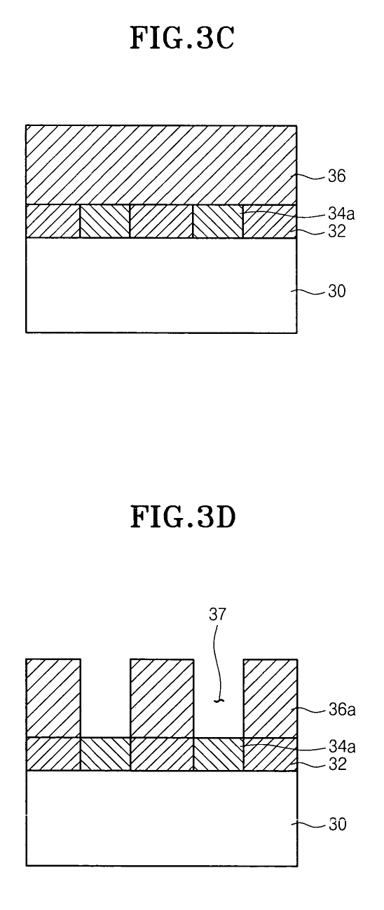

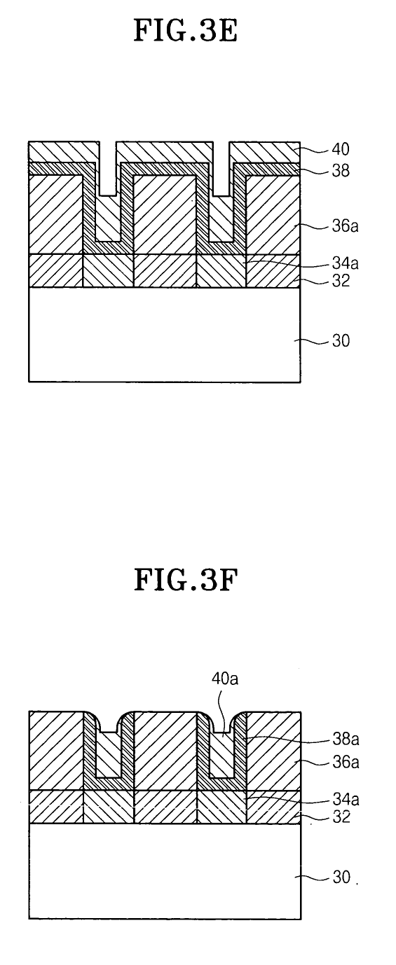

FIGS. 3A to 3F are sectional views showing a method for forming a copper inductor according to a third embodiment of the present invention.

Referring to FIG. 3A, a first photoresist pattern 32 having a first trench 33 is formed on a substrate 30. Subsequently, a first copper seed layer (not shown) is formed on a sidewall of the first trench 33, a bottom surface of the first trench 33, and the first photoresist pattern 32. Thereafter, the first copper seed layer is processed through CMP process in such a manner that the first photoresist pattern 32 is exposed.

The first photoresist pattern 32 is formed in the same manner as described in FIG. 2A, the first copper seed layer is formed in the same manner as described in FIG. 2B, and the CMP process for the first copper seed layer is performed in the same manner as described in FIG. 2C.

As a result, a first copper seed layer pattern 34 is formed on the sidewall of the first trench 33 and the bottom surface of the first trench 33.

Referring to FIG. 3B, the first photoresist pattern 32 and the first copper seed layer pattern 34 formed on the sidewall of the first trench 33 are removed to a height of the first copper seed layer pattern 34 formed on the bottom surface of the first trench 33.

Accordingly, a trench structure 34a filled with the first copper seed layer pattern 34 is formed on the substrate 30.

After exposing the surface of the photoresist pattern 32, the first photoresist pattern 32 and the first copper seed layer pattern 34 formed on the sidewall of the first trench 33 can be removed by polishing the first photoresist pattern 32 and the first copper seed layer pattern 34 formed at the sidewall of the first trench 33 together in-situ. Also, the first photo pattern 32 and the first copper seed layer pattern 34 formed at the sidewall of the first trench 33 can be removed by etching the first copper seed layer pattern 34 formed at the sidewall of the trench 33 due to an etching selectivity when the first photoresist pattern 32 is etched by using a solvent.

Referring to FIGS. 3C and 3D, a second photoresist film 36 is formed on the substrate 30 having the trench structure 34a. Subsequently, the second photoresist film 36 is partially removed through the exposure and development processes, thereby forming a second trench 37 exposing a surface of the trench structure 34a.

Accordingly, a second photoresist pattern 36a, which has the second trench 37 exposing the surface of the trench structure 34a, is formed on the substrate 30.

Referring to FIG. 3E, a second copper seed layer 38 is continuously formed on a sidewall of the second trench 37, a bottom surface of the second trench 37, and the second photoresist pattern 36a. Subsequently, a copper layer 40 is formed on the second copper seed layer 38. It is preferred to form the second copper seed layer 38 by using the deposition process (chemical vapor deposition or physical vapor deposition) and to form the copper layer 40 by using the electroplating process.

Accordingly, the second copper seed layer 38 and the copper layer 40 are sequentially formed on the sidewall of the second trench 37, the bottom surface of the second trench 37, and the second photoresist pattern 36.

Referring to FIG. 3F, the copper layer 40 and the second copper seed layer 38 are sequentially removed in such a manner that a surface of the second photoresist pattern 36a is exposed. It is preferred that the copper layer 40 and the second. copper seed layer 38 are removed through the CMP process described with reference to FIG. 2C.

Accordingly, a second copper seed layer pattern 38a and a copper layer pattern 40a are formed on the sidewall of the second trench 37 and the bottom surface of the second trench 37 on the substrate 30.

Therefore, according to the above-described method, a copper inductor having the trench structure 34a, the second copper seed layer pattern 38a, and the copper layer pattern 40a can be formed. That is, according to the above-described method, a bottom electrode and a column electrode of the copper inductor and the like can be formed.

Slurry including polycarboxylate polymer is used for the CMP process, polishing pressure is adjusted to about 1 psi, and the polishing rate is adjusted to about 18,000 Å/min, thereby reducing an influence of the CMP process on the first photoresist pattern and the second photoresist pattern. For this reason, it is possible to easily form an inductor having a required pattern according to the above-described method.

Also, although it is not shown, it is possible to perform an additional process for filling a trench formed by means of the copper layer pattern 40a with the copper layer. It is preferred to fill the trench with the copper layer by performing the deposition process such as the electroplating process.

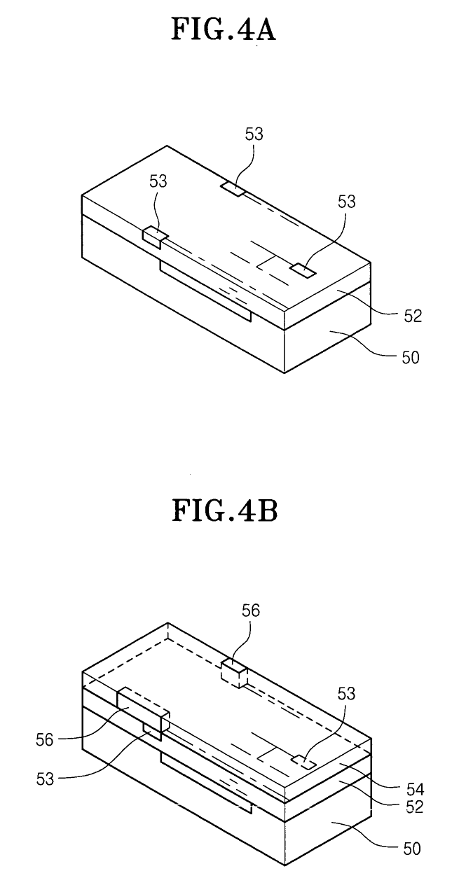

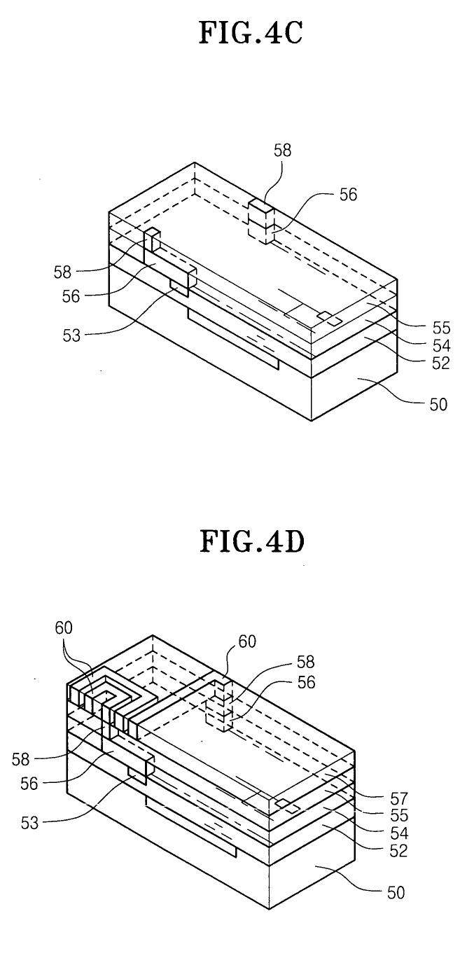

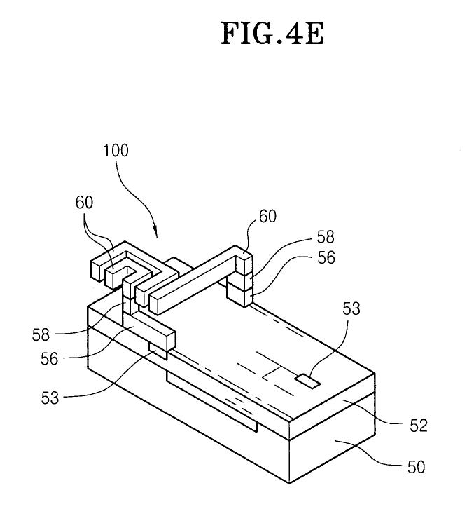

FIGS. 4A to 4E are perspective views showing a method for forming a copper inductor according to a fourth embodiment of the present invention.

The fourth embodiment is a method for forming a copper inductor by utilizing the third embodiment, in which an MEMS copper inductor is integrated on a CMOS (complementary metal oxide semiconductor) chip by using a process identical to a stacked type inductor fabricating process.

Referring to FIG. 4A, a pad 53 for a constant voltage, grounding, a control voltage, and an output is formed on a substrate 50 having an oxide layer 52.

Referring to FIG. 4B, a bottom electrode of the inductor 56 connected with the pad 53 is formed. Concretely, after forming a first photoresist pattern 54 having a first trench, a process is performed so as to fill the first trench with the copper layer and the copper seed layer. At this time, after forming the copper seed layer and the copper layer, a polishing process is carried out so as to expose a surface of the first photoresist pattern 54. The polishing process is the same as the CMP process according to the third embodiment. For this reason, it is possible to reduce damage to the first photoresist pattern 54 when performing the above polishing process.

Accordingly, it is possible to easily obtain the bottom electrode 56 of the inductor including the first trench filled with the copper seed layer and the copper layer.

Referring to FIG. 4C, a column electrode 58 of the inductor is formed, in which the column electrode 58 is partially connected with the bottom electrode 56 of the inductor. Concretely, after forming a second photoresist pattern 55 having a second trench, a process is performed so as to fill the second trench with the copper seed layer and the copper layer. At this time, after forming the copper seed layer and the copper layer, the polishing process is carried out so as to expose a surface of the second photoresist pattern 55. The polishing process is the same as the CMP process according to the third embodiment. For this reason, it is possible to reduce damage to the second photoresist pattern 55 when performing the above polishing process.

Accordingly, it is possible to easily obtain the column electrode 58 of the inductor including the second trench filled with the copper seed layer and the copper layer.

Referring to FIG. 4D, an upper electrode 60 of the inductor is formed, in which the upper electrode 60 is partially connected with the column electrode of the inductor 58. Concretely, after forming a third photoresist pattern 57 having a third trench, a process is performed so as to fill the third trench with the copper seed layer and the copper layer. At this time, after forming the copper seed layer and the copper layer, a polishing process is performed so as to expose a surface of the photoresist pattern 57. The polishing process is also the same as the CMP process according to the third embodiment. For this reason, damage to the third photoresist pattern 55 can be reduced when performing the above polishing process.

Accordingly, it is possible to easily obtain the upper electrode 60 of the inductor including the third trench filled with the copper seed layer and the copper layer.

Referring to 4E, the first, second, and third photoresist patterns 54, 55, and 57 formed on the substrate 50 are removed by means of a solvent. As a result, a stacked type copper inductor 100 is formed on the substrate 50.

Since the inductor includes copper, the inductor has a low specific resistance. For this reason, the copper inductor has a sufficient integration degree. Since the CMP process is carried out at a high polishing rate and under low polishing pressure during the polishing process for the copper payer, the copper inductor having the above property can be achieved.

As described above, the present invention provides a high polishing rate and low polishing pressure as process conditions when the CMP process is performed with respect to the copper layer, so that the copper layer can be actively utilized. In particular, an integration degree of the semiconductor device can be improved by applying the present invention to a fabrication of a semiconductor device such as an inductor having an MEMS.

Although a preferred embodiment of the present invention has been described for illustrative purposes, those skilled in the art will appreciate that various modifications, additions and substitutions are possible, without departing from the scope and spirit of the invention as disclosed in the accompanying claims.

1. A method for polishing a copper layer, the method comprising the steps of:
a) forming the copper layer on a substrate; and
b) polishing the copper layer through a CMP process, in which slurry having a polishing rate of at least 10,000 Å/min with respect to the copper layer is used.

2. The method as claimed in claim 1, wherein, in step (b), the CMP process is carried out under polishing pressure of 0.1 to 2 psi.

3. The method as claimed in claim 1, wherein, in step (b), slurry including polycarboxylate polymer is used.

4. A method for forming a copper layer wiring, the method comprising the steps of:
a) forming a sacrificial layer pattern having a trench on a substrate;
b) continuously forming a copper layer on a sidewall of the trench, a bottom surface of the trench, and the sacrificial layer pattern; and
c) polishing the copper layer through a CMP process by using slurry having a polishing rate of at least 10,000 Å/min with respect to the copper layer, thereby exposing a surface of the sacrificial layer pattern.

5. The method as claimed in claim 4, wherein, in step (c), slurry including polycarboxylate polymer is used and the CMP process is carried out under polishing pressure of 0.1 to 2 psi.

6. A method for forming a copper layer wiring, the method comprising the steps of:
a) forming a first sacrificial layer pattern having a first trench on a substrate;
b) continuously forming a first copper seed layer on a sidewall of the first trench, a bottom surface of the first trench, and the first sacrificial layer pattern;
c) polishing the first copper seed layer through a CMP process by using slurry having a polishing rate of at least 10,000 Å/min with respect to the first copper seed layer, thereby exposing a surface of the first sacrificial layer pattern;
d) removing the first sacrificial layer pattern to a height of the first copper seed layer formed on the bottom surface of the first trench, thereby forming a trench structure having the first trench filled with the first copper seed layer;
e) forming a second sacrificial layer pattern having a second trench, which exposes the trench structure, on the first sacrificial layer pattern having the trench structure;
f) continuously forming a second copper seed layer on a sidewall of the second trench, a bottom surface of the second trench, and the second sacrificial layer pattern;
g) continuously forming a copper layer on the second copper seed layer; and
h) sequentially removing the copper layer and the second copper seed layer, thereby exposing a surface of the second sacrificial layer pattern.

7. The method as claimed in claim 6, wherein the first and the second sacrificial layer patterns include a photoresist pattern.

8. The method as claimed in claim 6, wherein, in step (c), the CMP process is performed for the first copper seed layer by using slurry including polycarboxylate polymer under polishing pressure of 0.1 to 2 psi.

9. The method as claimed in claim 6, wherein, in step (d), the first sacrificial layer pattern is removed through an etching process using solvent or the CMP process.

10. The method as claimed in claim 6, wherein, in step (g), the copper layer is formed through an electroplating process, a chemical vapor deposition, or a physical vapor deposition.

11. The method as claimed in claim 6, wherein, in step (h), the copper layer and the second copper seed layer are sequentially removed through a CMP process using slurry.

12. The method as claimed in claim 11, wherein the CMP process is carried out by using slurry having a polishing rate of at least 10,000 Å/min with respect to the copper layer and the second copper seed layer.

13. The method as claimed in claim 11, wherein the CMP process is performed by using slurry including polycarboxylate polymer under polishing pressure of 0.1 to 2 psi.
